(19) United States
(12) Patent Application Publication
(10) Pub. No.: US 2024/0030129 A1
(43) Pub. Date: Jan. 25, 2024

(54) SEMICONDUCTOR DEVICE AND FORMATION METHOD THEREOF

(71) Applicant: Semiconductor Manufacturing International (Shanghai) Corporation, Shanghai (CN)

(72) Inventors: Bingkun CHEN, Shanghai (CN); Binbin SU, Shanghai (CN); Xianyong PU, Shanghai (CN); Lianguo ZHAO, Shanghai (CN); Yunpeng PENG, Shanghai (CN)

(21) Appl. No.: 18/224,689

(22) Filed: Jul. 21, 2023

(30) Foreign Application Priority Data
Jul. 22, 2022 (CN) 202210868035.1

(51) Int. Cl. H01L 23/522; H01L 21/768

(52) U.S. Cl. CPC H01L 23/5228; H01L 28/24; H01L 21/76802

(57) ABSTRACT

A semiconductor device includes a substrate, a metal layer formed on the substrate, a dielectric layer formed on the substrate and covering the metal layer, a first contact hole formed in the dielectric layer, a conductive layer filled in the first contact hole, a thin film resistor layer formed on a portion of the dielectric layer, and a cover layer located on the thin film resistor layer. A bottom of the first contact hole exposes a surface of the metal layer. A bottom of the thin film resistor layer contacts a top surface of the conductive layer.

### CROSS-REFERENCE TO RELATED APPLICATION

This application claims the priority of Chinese Patent Application No. 202210868035.1, filed on Jul. 22, 2022, the entire content of which is hereby incorporated by reference.

### FIELD OF THE DISCLOSURE

The present disclosure generally relates to the field of semiconductor manufacturing technology and, more particularly, relates to a semiconductor device and a formation method of the semiconductor device.

### BACKGROUND

A semiconductor integrated circuit (IC) typically includes a metallization layer. The metallization layer is used to connect various components of the IC, which are referred to as interconnects or back-end-of-line (BEOL) elements. Copper is often preferred over aluminum due to lower resistivity and higher electromigration resistance of copper. However, copper interconnects are typically difficult to manufacture using a conventional photoresist mask and plasma etching employed for aluminum interconnects.

One technology for forming a copper interconnect on an IC is called damascene patterning, sometimes referred to as an inlay process, which involves conventional metal filling technology. The inlay process can include patterning a dielectric material, such as silicon dioxide, fluorinated silica glass (FSG), or organosilica glass (OSG) with a trench opening, where copper or another metal conductor is included. A copper diffusion barrier layer (i.e., Ta, TaN, or two layers of Ta and TaN) is then deposited, and a copper seed layer is then deposited. Then, bulk copper is filled using, for example, an electrochemical plating process. Excess copper and the barrier layer can then be removed using a chemical mechanical planarization (CMP) process, which is referred to as a copper CMP process. The copper remaining in the trench is used as a conductor. A dielectric barrier layer (e.g., SiN or SiC) is typically deposited on a wafer to prevent copper corrosion and enhance device reliability.

As more feature components are packaged into an individual semiconductor chip, passive components such as resistors need to be increasingly integrated into the circuit. Some resistors can be formed through ion implantation and diffusion, such as polysilicon resistors. However, such resistors often have high resistance variation and resistance values that change significantly with temperature. A new method has been introduced to form an integrated resistor, which is referred to as a thin-film resistor (TFR), to improve resistor performance.

However, the performance of the semiconductor devices formed by the existing technology is poor.

### BRIEF SUMMARY OF THE DISCLOSURE

The present disclosure provides a semiconductor device and a method for forming the semiconductor device to improve the performance of the semiconductor device.

One aspect of the present disclosure includes a semiconductor device, including a substrate, a metal layer formed on the substrate, a dielectric layer formed on the substrate and covering the metal layer, a first contact hole formed in the dielectric layer, a conductive layer filled in the first contact hole, a thin film resistor layer formed on a portion of the dielectric layer, and a cover layer located on the thin film resistor layer. A bottom of the first contact hole exposes a surface of the metal layer. A bottom of the thin film resistor layer contacts a top surface of the conductive layer.

In some embodiments, the semiconductor device further includes a second contact hole formed in the dielectric layer and the cover layer. The second contact penetrates the dielectric layer and the cover layer. A bottom of the second contact hole exposes the surface of the metal layer.

In some embodiments, the semiconductor device further includes a second conductive layer filled in the second contact hole.

In some embodiments, the semiconductor device further includes a second metal layer formed on the cover layer. A bottom surface of the second metal layer contacts a top of the second conductive layer.

Another aspect of the present disclosure includes a method for forming a semiconductor device. The method includes providing a substrate, forming a metal layer on the substrate, forming a dielectric layer on the substrate, forming a first contact hole in the dielectric layer, forming a conductive layer in the first contact hole, forming a thin film resistor layer on a portion of the dielectric layer, and forming a cover layer on the thin film resistor layer and the dielectric layer. The dielectric layer covers the metal layer. A bottom of the first contact hole exposes a surface of the metal layer. A bottom of the thin film resistor layer contacts a top of the conductive layer. The cover layer covers the thin film resistor layer.

In some embodiments, the method further includes, after forming the cover layer, forming a second contact hole in the cover layer and the dielectric layer. The second contact hole penetrates the dielectric layer and the cover layer, and a bottom of the second contact hole exposes the surface of the metal layer.

In some embodiments, the method further includes forming a second conductive layer in the second contact hole.

In some embodiments, the method further includes forming a second metal layer on the cover layer. A bottom surface of the second metal layer contacts a top surface of the second conductive layer.

As disclosed, the technical solutions of the present disclosure have the following advantages.

In the technical solution of the present disclosure, the thin-film resistor layer is formed on a portion of the dielectric layer. The bottom of the thin film resistor layer contacts the top of the conductive layer. The bottom of the conductive layer contacts the metal layer. In such a structure, the thin film resistor layer can be directly connected to the metal layer. A connection layer of the thin film resistor may not need to be formed in the dielectric layer. On one hand, the process flow can be simplified. The process flow can be well-compatible in the back-end fabrication process of the back-end-of-line (BEOL) element without changing the resistor characteristics. On another hand, the etching process may only need to be performed once in the process of forming the thin-film resistor layer, which saves the deposition and etching of the conventional connection layer. The damage to the sidewall of the connection layer can be avoided, and the risk of exposing the metal layer in the wet etching of the conventional connection layer can be avoided. Thus, the exposure time of the thin film resistor layer can be greatly shortened, and the quality of the main body of the formed thin film resistor can be ensured, which forms the basis for forming a good quality semiconductor device.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic structural diagram of a semiconductor device consistent with the disclosed embodiments of the present disclosure.

FIGS. 2 to 10 illustrate schematic structural diagrams showing a formation process of a semiconductor device consistent with the disclosed embodiments of the present disclosure.

FIG. 11 illustrates an exemplary process for forming a semiconductor device consistent with the disclosed embodiments of the present disclosure.

### DETAILED DESCRIPTION

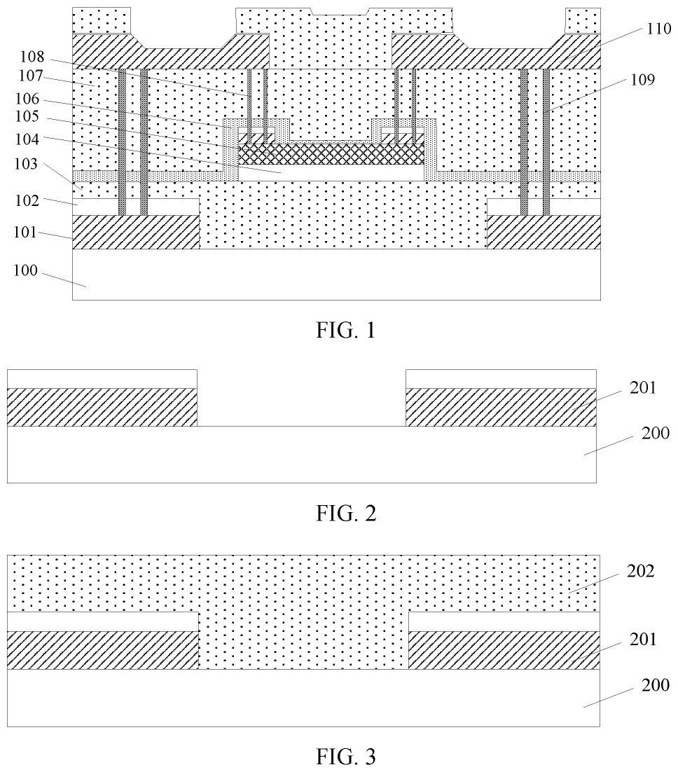

FIG. 1 illustrates a schematic structural diagram of the semiconductor device. The semiconductor device includes a substrate dielectric layer 100, a metal layer 101 over an upper portion of the substrate dielectric layer 100, an anti-reflective layer 102 over the metal layer 101, a dielectric layer 103 over the substrate dielectric layer 100 and covering the metal layer 101, an anti-reflective layer 104 over a portion of the dielectric layer 103, a thin-film resistor layer 105 over the anti-reflective layer 104, a connection layer 106 formed separately over the thin-film resistor layer 105, a cover layer 107 formed over the dielectric layer 103 and covering the connection layer 106 and the thin-film resistor layer 105, a first contact hole (not shown in the figure) formed in the cover layer 107 and exposing a surface of the connection layer 106 at the bottom, a conductive layer 108 filled in the first contact hole, a second contact hole (not shown in the figure) formed in the cover layer 107 and the dielectric layer 103, penetrating through the dielectric layer 103 and the cover layer 107, and exposing a surface of the metal layer 101 at the bottom of the second contact hole, a second conductive layer 109 filled in the second contact hole, and a second metal layer 110 formed on the cover layer 107. The bottom of the second metal layer 110 is electrically connected to the conductive layer 108 and the second conductive layer 109.

The inventors have found that by directly connecting the thin-film resistor layer to the metal layer, an additional thin-film resistor structure does not need to be formed on the dielectric layer. On one hand, in a process of forming the first contact hole and the second contact hole, an additional load is required on the connection layer 106 and the metal layer 101, and the height of the connection layer is relatively high and causes significant challenges for dry etching. Meanwhile, in a process of forming the connection layer 106, a portion of a sidewall of the connection layer 106 is etched by wet etching, and a process window is narrow, which can cause a risk of batch scrap when a system breakdown. Then, the metal layer has a contamination leakage risk. Moreover, in a process of patterning the thin film resistor layer 105, two times of dry etching and one time of wet etching are performed. The process is complex, which affects the productivity of the semiconductor device, and the exposure time is long which affects the quality of the main body of the thin film resistor layer 105.

The inventors have found that the thin film resistor layer is on a portion of the dielectric layer, and the bottom of the thin film resistor layer contacts the top of the conductive layer. The bottom of the conductive layer contacts with the metal layer. In this structure, the thin film resistor layer is directly connected to the metal layer, and another such thin film resistor structure does not need to be formed in the dielectric layer. On one hand, the processing process is simplified, and the thin film resistor layer is well-compatible in the backend fabrication process of the back-end-of-line (BEOL) element without changing the resistor characteristics. On another hand, the etching process may only need to be performed once in the process of forming the thin-film resistor layer, which saves the deposition and etching of the conventional connection layer. The damage to the sidewall of the connection layer can be avoided, and the risk of exposing the metal layer in the wet etching of the conventional connection layer can be avoided. Thus, the exposure time of the thin film resistor layer can be greatly shortened, and the quality of the main body of the formed thin film resistor can be ensured, which forms the basis for forming a good quality semiconductor device.

To cause the purposes, features, and advantages of the present disclosure more obvious and understandable, embodiments of the present disclosure are described in detail in connection with the accompanying drawings.

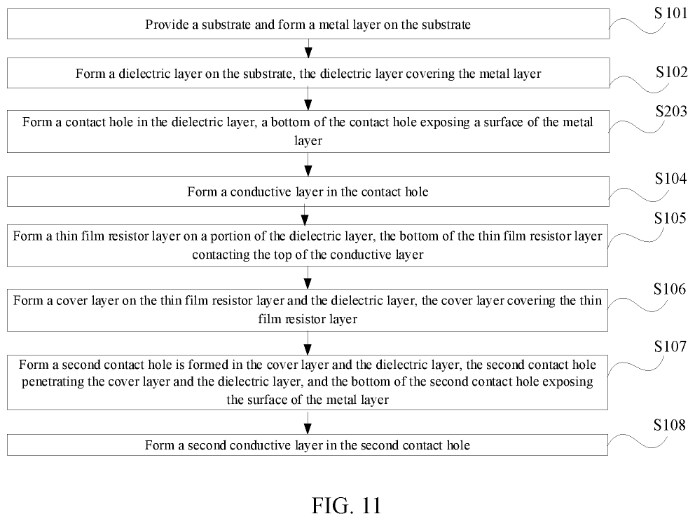

FIG. 11 illustrates an exemplary process for forming a semiconductor device consistent with the disclosed embodiments of the present disclosure. FIGS. 2 to 10 illustrate schematic structural diagrams showing a formation process of the semiconductor device consistent with the disclosed embodiments of the present disclosure.

As shown in FIG. 11, a substrate is provided, and a metal layer is formed on the substrate (S101). FIG. 2 illustrates a corresponding semiconductor structure.

Referring to FIG. 2, a substrate 200 is provided, and a metal layer 201 is formed on the substrate 200.

In some embodiments, the metal layer 201 is discretely arranged on the substrate 200.

In some embodiments, the substrate 200 includes a base substrate, a storage device and a logic device on the base substrate, and a dielectric layer or an oxide layer formed on the storage device and the logic device.

In some embodiments, forming the metal layer 201 can include forming an initial metal layer on the substrate 200, patterning the initial metal layer, and forming a metal layer 201 discretely arranged on the substrate 200.

In some embodiments, a material of the metal layer 201 can be aluminum.

In some other embodiments, the material of the metal layer 201 can also include copper, nickel, etc.

In some embodiments, a protective layer (not marked in the figure) can be further formed on the metal layer 201.

As shown in FIG. 11, a dielectric layer is formed on the substrate, where the dielectric layer covers the metal layer (S102). FIG. 3 illustrates a corresponding semiconductor structure.

Referring to FIG. 3, a dielectric layer 202 is formed on the substrate 200. The dielectric layer 202 covers the metal layer 201.

In some embodiments, the material of the dielectric layer 202 can be silicon oxide.

In some other embodiments, the material of the dielectric layer 202 can also include doped silicon nitride, silicon nitride boride, silicon oxycarbide, or silicon oxynitride.

In some embodiments, the dielectric layer 202 can be formed on the substrate 200 using a chemical vapor deposition method. Process parameters for the chemical vapor deposition process can include gases such as oxygen, ammonia (NH₃), and N(SiH₃)₃, an oxygen flow rate of to 10000 sccm, an ammonia (NH₃) flow rate of 20 sccm to 10000 sccm, an N(SiH₃)₃ flow rate of 20 sccm to 10000 sccm, a chamber pressure of 0.01 to 10 Torr, and a temperature of 30° C. to 90° C.

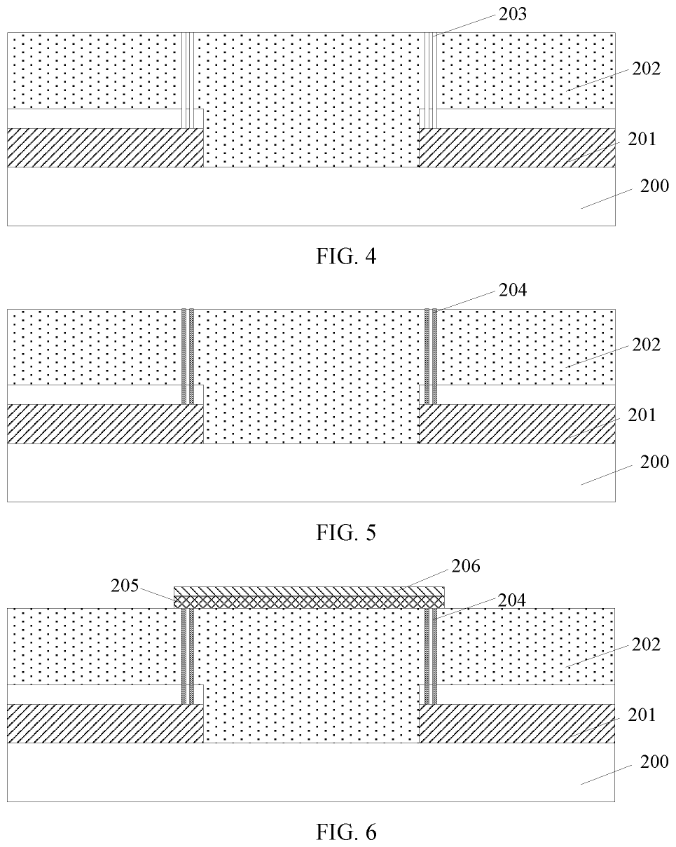

As shown in FIG. 11, a first contact hole is formed in the dielectric layer, where a bottom of the first contact hole exposes a surface of the metal layer (S103). FIG. 4 illustrates a corresponding semiconductor structure.

Referring to FIG. 4, a first contact hole 203 is formed in the dielectric layer 202. The bottom of the first contact hole 203A exposes a surface of the metal layer 201.

In some embodiments, the first contact hole 203 can be formed by dry etching.

In some embodiments, process parameters of a dry etching process can include gases such as CF₄ and CH₃F, a CF4 flow rate of 20 sccm to 200 sccm, a CH3F flow rate of 20 sccm to 50 sccm, a source RF power of 200 watts to 500 watts, and a chamber pressure of 1 Torr to 10 Torr.

In some embodiments, the first contact hole 203 is configured to provide space for subsequently forming a conductive layer. Thus, the electrical performance of the semiconductor device can be realized using the conductive layer.

In other embodiments, the first contact hole 203 can be further formed using a wet etching process.

In some embodiments, an initial anti-reflective layer (not marked in the figure) can be formed on the dielectric layer 202.

As shown in FIG. 11, a conductive layer is formed in the first contact hole (S104). FIG. 5 illustrates a corresponding semiconductor structure.

Referring to FIG. 5, a conductive layer 204 is formed in the first contact hole 203.

In some embodiments, a material of the conductive layer 204 can be a metal. Thus, the conductive layer 204 can have conductivity when the device is subsequently powered on to realize the electrical performance of the semiconductor device.

In some embodiments, the process for forming the conductive layer 204 can be a chemical vapor deposition process.

In some other embodiments, the process for forming the conductive layer 204 can also include an electroplating process or a selective growth process.

As shown in FIG. 11, a thin film resistor layer is formed on a portion of the dielectric layer, where the bottom of the thin film resistor layer contacts the top of the conductive layer (S105). FIG. 6 illustrates a corresponding semiconductor structure.

Referring to FIG. 6, a thin film resistor layer 205 is formed on a portion of the dielectric layer 202. The bottom of the thin film resistor layer 205 contacts the top of the conductive layer 204.

In some embodiments, a process for forming the thin film resistor layer 205 can be a sputtering process. The thin film resistor layer 205 can be sputtered on the conductive layer 204 and a portion of the dielectric layer 202.

In some embodiments, the bottom of the thin film resistor layer 205 can directly contact the top of the conductive layer 204. On one hand, the process flow can be simplified. The thin film resistor layer 205 can be well compatible with the back-end fabrication process of the backend-of-line (BEOL) element. The resistor characteristics can remain unchanged. On another hand, the etching process may only need to be performed once in the process of forming the thin-film resistor layer 205, which saves the deposition and etching of the conventional connection layer. The damage to the sidewall of the connection layer can be avoided, and the risk of exposing the metal layer 201 in the wet etching of the conventional connection layer can be avoided. Thus, the exposure time of the thin film resistor layer can be greatly shortened, and the quality of the main body of the formed thin film resistor can be ensured, which forms the basis for forming a good quality semiconductor device.

In some embodiments, a material of the thin film resistor layer 205 can be CrSi.

In some other embodiments, the material of the thin film resistor layer 205 can also be SiCCr, TaN, NiCr, etc.

In some embodiments, an anti-reflective layer 206 is also formed on the thin film resistor layer 205. A material of the anti-reflective layer 206 can be SiON.

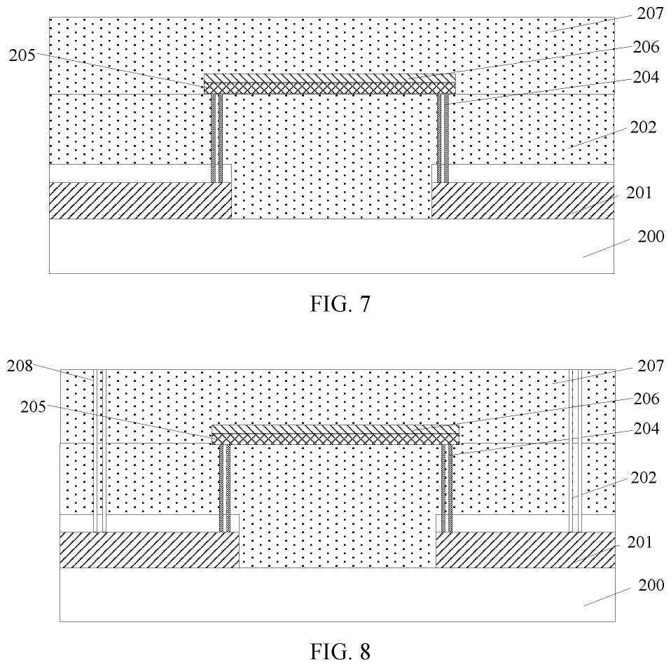

As shown in FIG. 11, a cover layer is formed on the thin film resistor layer and the dielectric layer, where the cover layer covers the thin film resistor layer (S106). FIG. 7 illustrates a corresponding semiconductor structure.

Referring to FIG. 7, a cover layer 207 is formed on the thin film resistor layer 205 and the dielectric layer 202. The cover layer 207 covers the thin film resistor layer 205.

In some embodiments, the cover layer 207 is formed on the anti-reflective layer 206 and the dielectric layer 202, covering the anti-reflective layer 206.

In some embodiments, a process for forming the cover layer 207 can be a chemical vapor deposition process.

In some embodiments, a material of the cover layer 207 can be silicon oxide.

In other embodiments, the material of the cover layer 207 can also be silicon nitride, silicon nitride boride, silicon oxycarbide, or silicon oxynitride.

As shown in FIG. 11, a second contact hole is formed in the cover layer and the dielectric layer, where the second contact hole penetrates the cover layer and the dielectric layer, and the bottom of the second contact hole exposes the surface of the metal layer (S107). FIG. 8 illustrates a corresponding semiconductor structure.

Referring to FIG. 8, a second contact hole 208 is formed in the cover layer 207 and the dielectric layer 202. The second contact hole 208 penetrates the cover layer 207 and the dielectric layer 202. The surface of the metal layer 201 is exposed at the bottom of the second contact hole 208.

In some embodiments, the metal layer 201 can include at least one first contact hole 203 and at least one second contact hole 208.

In some embodiments, the second contact hole 208 can be formed to provide space for subsequently forming a second conductive layer.

In some embodiments, the thin film resistor layer 205 may not be exposed in the process of forming the second contact hole 208. Thus, the thin film resistor layer 205 may not be damaged, and the quality of the main body of the thin film resistor can be ensured, which forms the basis for forming the semiconductor device with high quality.

In some embodiments, the process for forming the second contact hole 208 can be a dry etching process.

In some other embodiments, the process for forming the second contact hole 208 can also be a wet etching process.

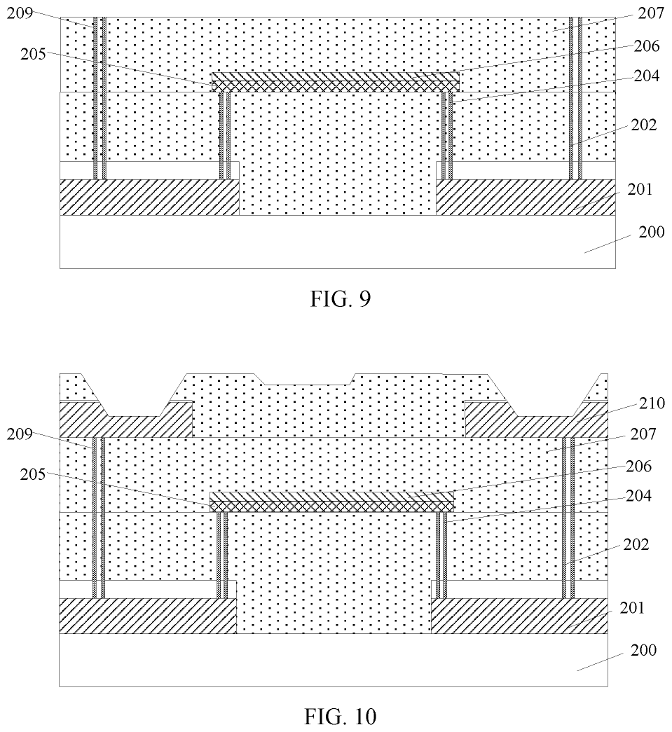

As shown in FIG. 11, a second conductive layer is formed in the second contact hole (S108). FIG. 9 illustrates a corresponding semiconductor structure.

Referring to FIG. 9, a second conductive layer 209 is formed within the second contact hole 208.

In some embodiments, the second conductive layer 209 can be a metal. Thus, the second conductive layer 209 can be conductivity when the device is powered on, thereby realizing the electrical performance of the semiconductor device.

In some embodiments, the process for forming the second conductive layer 209 can be a chemical vapor deposition process.

In some other embodiments, the process for forming the second conductive layer 209 can also include an electroplating process or a selective growth process.

Referring to FIG. 10, a second metal layer 210 is formed on the cover layer 207. A bottom surface of the second metal layer 210 contacts a top surface of the second conductive layer 209.

In some embodiments, forming the second metal layer 210 can include forming an initial second metal layer on the cover layer 207, forming a patterned layer on the initial second metal layer, etching the initial second metal layer using the patterned layer as a mask, forming the second metal layer 210 on the cover layer 207, and removing the patterned layer.

In some embodiments, a material of the second metal layer 210 can be aluminum.

In some other embodiments, the material of the second metal layer 210 can also include copper, silver, etc.

In some embodiments, planarization is performed after the initial second metal layer.

In some embodiments, after forming the second metal layer 210, an n-th interconnect structure can be subsequently formed one over another, which is not repeated here.

Accordingly, referring to FIG. 10, the present disclosure also provides a semiconductor device. The semiconductor device includes a substrate 200, a metal layer 201 on the substrate 200, a dielectric layer 202 formed on the substrate 200 and covering the metal layer 201, a first contact hole 203 formed in the dielectric layer 202 and exposing the surface of the metal layer 201 at the bottom of the first contact hole 203, a conductive layer 204 filled in the first contact hole 203, and a thin film resistor layer 205 formed on the dielectric layer 202 and contacting the top of the conductive layer 204 at the bottom of the thin film resistor layer 205.

In some embodiments, in the structure of the semiconductor device, the thin film resistor layer 205 can be directly connected to the metal layer 201. The connection layer of the thin film resistor may not need to be formed on the dielectric layer 202. On one hand, the process flow can be simplified, and the thin film resistor can be well-compatible in the fabrication process of the backend-of-line (BEOL) element. The resistor characteristics can remain unchanged. On another hand, the etching process may only need to be performed once in the process of forming the thin-film resistor layer, which saves the deposition and etching of the conventional connection layer. The damage to the sidewall of the connection layer can be avoided, and the risk of exposing the metal layer 201 in the wet etching of the conventional connection layer can be avoided. Thus, the exposure time of the thin film resistor layer can be greatly shortened, and the quality of the main body of the formed thin film resistor can be ensured, which forms the basis for forming a good quality semiconductor device.

In some embodiments, the semiconductor device further includes a cover layer 207 formed on the dielectric layer 202 and covering the thin film resistor layer 205.

In some embodiments, the semiconductor device further includes a second contact hole 208 formed in the dielectric layer 202 and the cover layer 207 and penetrating the dielectric layer 202 and the cover layer 207. The surface of the metal layer 201 is exposed at the bottom of the second contact hole 208.

In some embodiments, the semiconductor device further includes a second conductive layer 209 filled in the second contact hole 208.

In some embodiments, the semiconductor device further includes a second metal layer 210 formed on the cover layer 207. The bottom surface of the second metal layer 210 contacts the top surface of the second conductive layer 209.

Although the present disclosure is described above, the present disclosure is not limited to this. Those skilled in the art can make various changes and modifications without departing from the spirit and scope of the present disclosure. Those changes and modifications are within the scope of the present disclosure. The scope of the present disclosure should be subject to the claims.

What is claimed is:

1. A semiconductor device comprising:
a substrate;
a metal layer formed on the substrate;
a dielectric layer formed on the substrate and covering the metal layer;
a first contact hole formed in the dielectric layer, a bottom of the first contact hole exposing a surface of the metal layer;
a conductive layer filled in the first contact hole;
a thin film resistor layer formed on a portion of the dielectric layer, a bottom of the thin film resistor layer contacting a top surface of the conductive layer; and
a cover layer located on the thin film resistor layer.

2. The semiconductor device according to claim 1, further comprising:
a second contact hole formed in the dielectric layer and the cover layer and penetrating the dielectric layer and the cover layer, a bottom of the second contact hole exposing the surface of the metal layer.

3. The semiconductor device according to claim 2, further comprising:
a second conductive layer filled in the second contact hole.

4. The semiconductor device according to claim 3, further comprising:
a second metal layer formed on the cover layer, a bottom surface of the second metal layer contacting a top of the second conductive layer.

5. The semiconductor device according to claim 1, wherein the substrate includes:
a base substrate;
a storage device; and
a logic device formed on the base substrate.

6. The semiconductor device according to claim 5, wherein the dielectric layer is formed on the storage device and the logic device.

7. The semiconductor device according to claim 1, wherein a material of the metal layer is aluminum, copper, and nickel.

8. The semiconductor device according to claim 1, further comprising:
a protective layer formed on the metal layer.

9. The semiconductor device according to claim 1, wherein a material of the dielectric layer includes silicon oxide, silicon nitride, silicon nitride boride, silicon oxycarbide, or silicon oxynitride.

10. The semiconductor device according to claim 1, wherein a material of the thin film resistor layer includes CrSi, SiCCr, TaN, or NiCr.

11. A method for forming a semiconductor device comprising:
providing a substrate;
forming a metal layer on the substrate;
forming a dielectric layer on the substrate, the dielectric layer covering the metal layer;
forming a first contact hole in the dielectric layer, a bottom of the first contact hole exposing a surface of the metal layer;
forming a conductive layer in the first contact hole;
forming a thin film resistor layer on a portion of the dielectric layer, wherein a bottom of the thin film resistor layer contacts a top of the conductive layer; and
forming a cover layer on the thin film resistor layer and the dielectric layer, wherein the cover layer covers the thin film resistor layer.

12. The method according to claim 11, further comprising, after forming the cover layer:
forming a second contact hole in the cover layer and the dielectric layer, wherein the second contact hole penetrates the dielectric layer and the cover layer, and a bottom of the second contact hole exposes the surface of the metal layer.

13. The method according to claim 12, further comprising:
forming a second conductive layer in the second contact hole.

14. The method according to claim 13, further comprising:
forming a second metal layer on the cover layer, wherein a bottom surface of the second metal layer contacts a top surface of the second conductive layer.

15. The method according to claim 11, wherein the substrate includes:
a base substrate;
a storage device; and
a logic device formed on the base substrate.

16. The method according to claim 15, wherein forming the dielectric layer on the substrate includes:
forming the dielectric layer on the storage device and the logic device.

17. The method according to claim 11, wherein forming the metal layer includes:
forming an initial metal layer on the substrate;
patterning the initial metal layer; and
forming the metal layer discretely arranged on the substrate.

18. The method according to claim 11, further comprising:
forming a protective layer on the metal layer.

19. The method according to claim 11, wherein forming the dielectric layer includes:
forming the dielectric layer using a chemical vapor deposition method, wherein:
a process gas includes oxygen, ammonia (NH₃), and N(SiH₃)₃;
an oxygen flow rate ranges from 20 sccm to 10000 sccm;
an ammonia (NH₃) flow rate ranges from 20 sccm to 10000 sccm;
an N(SiH₃)₃ flow rate ranges from 20 sccm to 10000 sccm;
a chamber pressure ranges from 0.01 to 10 Torr; and
a temperature ranges from 30° C. to 90° C.

20. The method according to claim 11, wherein forming the first contact hole includes:
forming the first contact hole by dry etching, wherein:
a process gas includes CF₄ and CH₃F;
a CF₄ flow rate ranges from 20 sccm to 200 sccm;
a CH₃F flow rate ranges from 20 sccm to 50 sccm;
a source RF power ranges from 200 watts to 500 watts; and
a chamber pressure ranges from 1 Torr to 10 Torr.
